(19) United States
(12) Patent Application Publication
(10) Pub. No.: US 2014/0202738 A1
(43) Pub. Date: Jul. 24, 2014

(54) NANOSTRUCTURE TRANSPARENT CONDUCTORS HAVING HIGH THERMAL STABILITY FOR ESD PROTECTION

(71) Applicant: Cambrios Technologies Corporation, Sunnyvale, CA (US)

(72) Inventors: Pierre-Marc Allemand, San Jose, CA (US); Paul Mansky, San Francisco, CA (US); Florian Pschenitzka, San Francisco, CA (US); Michael A. Spaid, Mountain View, CA (US); Jonathan Westwater, Kawasaki-shi (JP)

(73) Assignee: Cambrios Technologies Corporation, Sunnyvale, CA (US)

(21) Appl. No.: 14/161,319

(22) Filed: Jan. 22, 2014

Related U.S. Application Data
(60) Provisional application No. 61/755,351, filed on Jan. 22, 2013.

(51) Int. Cl. H05K 1/02

(52) U.S. Cl. CPC H05K 1/0259; H05K 1/0298; Y10S 977/932; B82Y 30/00
USPC 174/251; 977/932

(57) ABSTRACT

Disclosed herein are transparent conductors having high thermal capacity and improved protection against electrostatic discharge.

### BACKGROUND

1. Technical Field

This invention is related to nanostructure-based transparent conductors having improved electrostatic discharge protection.

2. Description of the Related Art

Transparent conductors refer to thin conductive films coated on high-transmittance surfaces or substrates. Transparent conductors may be manufactured to have surface conductivity while maintaining reasonable optical transparency. Such surface conducting transparent conductors are widely used as transparent electrodes in flat liquid crystal displays, touch panels, electroluminescent devices, and thin film photovoltaic cells; as anti-static layers; and as electromagnetic wave shielding layers.

Currently, vacuum deposited metal oxides, such as indium tin oxide (ITO), are the industry standard materials for providing optical transparency and electrical conductivity to dielectric surfaces such as glass and polymeric films. However, metal oxide films are fragile and prone to damage during bending or other physical stresses. They also require elevated deposition temperatures and/or high annealing temperatures to achieve high conductivity levels. Moreover, the process of vacuum deposition is not conducive to forming patterns and circuits. This typically results in the need for costly patterning processes such as photolithography. In addition, a metal oxide film tends to have trouble properly adhering to certain substrates that are prone to adsorbing moisture, such as plastic and organic substrates (e.g., polycarbonates). Applications of metal oxide films on these flexible substrates are therefore severely limited.

In recent years there is a trend to replace current industry standard transparent conductive ITO films in flat panel displays with a composite material of interconnecting metal nanostructures (e.g., silver nanowires) embedded in a matrix, the matrix being insulating or conductive. Typically, a transparent conductive film is formed by first coating on a substrate a coating solution including metal nanowires, an optional binder and a volatile liquid carrier. The optional binder provides the matrix upon removal of the volatile components of the ink composition. Irrespective of the presence of a binder, an overcoat layer may be further coated after the deposition of the nanostructures. The overcoat layer typically comprises one or more polymeric or resin materials. The resulting transparent conductive film has a sheet resistance comparable or superior to that of the ITO films.

Nanostructure-based coating technologies are particularly suited for producing robust electronics on large-area, flexible substrates. See U.S. Pat. Nos. 8,049,333; 8,094,247; 8,018,568; 8,174,667; and 8,018,563 in the name of Cambrios Technologies Corporation, which are hereby incorporated by reference in their entirety. The solution-based format for forming nanostructure-based thin film is also compatible with existing coating and lamination techniques. Thus, additional thin films of overcoat, undercoat, adhesive layer, and/or protective layer can be integrated into a high through-put process for forming optical stacks that include nanostructure-based transparent conductors.

Other methods of forming transparent conductors include the use of a fine patterned low sheet resistance grid or mesh with a sputtered transparent conductor or conducting polymer to form a composite structure having the desired sheet resistance. Further, a combination of conductive nanostructures and sputtered grid or mesh can be used to achieve relatively low resistance transparent conductors.

There remains a need in the art to provide nanostructure-based transparent conductors having desirable electrical, optical and mechanical properties that sustain throughout the normal service life of the transparent conductor.

### BRIEF SUMMARY

Described herein are thin film transparent conductive layers that are thermally stable, in particular, against a high temperature gradient (e.g., a rapid temperature surge over a brief period of time) during an electrostatic discharge (ESD) event.

One embodiment provides a transparent conductive film, comprising: a substrate; a conductive layer disposed on the substrate, the conductive layer having a plurality of interconnecting conductive elements optionally embedded in a binder; and an overcoat layer overlying the conductive layer, wherein at least one of the binder and the overcoat is a thermally stable material.

In various embodiments, the binder may be a thermally stable material based on a thermally stable polymer, such as polyimide or polybenzoxazoles.

In other embodiments, the overcoat may be a thermally stable spin-on dielectrics, such as spin-on glass (SOG).

In further embodiments, the overcoat may comprise a plurality of high heat-capacity nanoparticles.

In various embodiments, the conductive layer may be a network of conductive nanostructures or a conductive mesh, or a combination thereof.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and they have been solely selected for ease of recognition in the drawings.

FIG. 1 illustrates one embodiment of a transparent conductor having a thermally stable overcoat.

FIGS. 2A-2C illustrate various configurations of a conductive layer according to embodiments of the present disclosure.

FIG. 3 illustrates another embodiment of a transparent conductor having a thermally stable overcoat that includes nanoparticle fillers having high heat capacity.

FIG. 4 illustrates a further embodiment of a transparent conductor having a thermally stable overcoat and a thermally stable undercoat.

### DETAILED DESCRIPTION

Described herein are various embodiments directed to mesh or nanostructure-based transparent conductors that are thermally stable and less prone to structural damage that could be caused by transient heating during an electrostatic discharge (ESD) event.

In the course of processing or handling transparent conductor films, an (ESD) event may occur when enough electrostatic charges accumulate and reach an electric field strength to sustain a spark. In such an event, the accumulated charges will move to a lower energy potential, such as a conductive layer in the vicinity. As the electrostatic energy discharges through the conductive layer, the current-carrying conductive elements in a thin film construction, e.g., mesh and/or nanostructures may be transiently heated to well above 200° C. It has been observed that film defects tend to occur after an ESD event, resulting in failures such as a reduction or total loss of electrical conductivity.

SEM images of transparent conductive films show that damage to the organic phase (polymeric binder or overcoat) may be associated with these failures. A potential failure mechanism is that heat from the conductive elements causes vaporization and decomposition of the polymer binder and/or overcoat, leading to rapid localized pressure buildup and subsequent outgassing, a process akin to an explosion in which the pressure buildup releases through an abrupt gas phase diffusion. The observed “explosions” in the organic phase could be a main source of mechanical damage to the nanostructures or mesh.

Thus, one embodiment provides a transparent conductor having a thermally stable overcoat or binder that can withstand the rapid temperature rise during the transient heating of the nanostructures. Thus, a material that is “thermally stable,” as used herein, should be able to tolerate high temperature gradient, i.e., large temperature changes (hundreds of degrees) over a very short period of time (on the scales of microseconds or seconds).

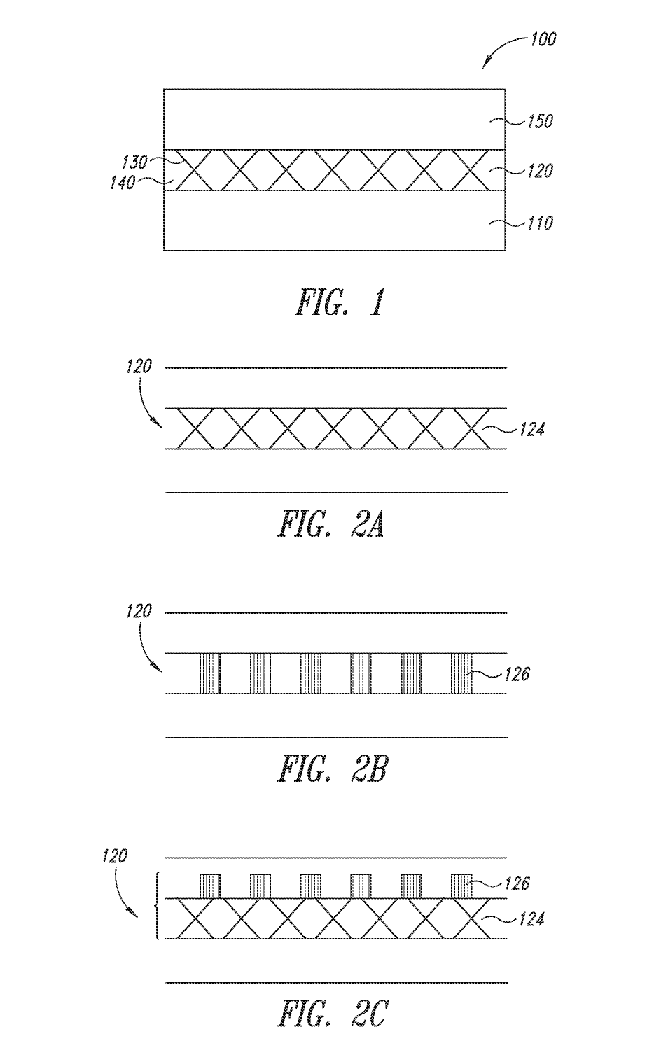

FIG. 1 shows a transparent conductive film (100) comprising a substrate (110), a thin film conductive layer (120) disposed on the substrate (110), the conductive layer (120) having a plurality of interconnecting conductive elements (130) embedded in binder (140), and an overcoat layer (150) overlying the nanostructure conductive layer. At least one of the binder and the overcoat is a thermally stable material, as defined herein.

In various embodiments, the conductive elements (130) may be a plurality of randomly intersecting conductive nanostructures. In other embodiment, the conductive elements are conductive mesh or grid. The conductive mesh or grid may be regularly or randomly intersecting. In other embodiments, the conductive elements may be a combination film of a plurality of nanostructures electrically coupled to one or more conductive mesh or grid. Such films are disclosed in co-pending U.S. patent application Ser. No. 13/287,881, which is incorporated by reference herein.

FIGS. 2A-2B schematically show the various conductive elements that form the thin film conductive layer (120) of FIG. 1.

In FIG. 2A, the conductive elements include a plurality of conductive nanostructures (124), in particular, metal nanowires. In a particularly preferred embodiment, the conductive nanostructures are silver nanowires. The conductive layer may be formed by a coating a coating composition of the nanostructures on a substrate (e.g., 110 of FIG. 1). The nanostructures are randomly distributed on the substrate, however, a sufficient number of the nanostructure are intersecting with each other to form a conductive network, which is capable of carrying an electrical current.

In FIG. 2B, the conductive layer (120) includes a conductive mesh or grid (126). A conductive mesh (grid) is a low resistance pathway or a network of pathways for current flow, distribution and/or collection. The low sheet resistance grid 126 includes any type of electrically conductive structure having appropriate electrical and physical properties, including metallic, non-metallic, or composite structures containing a combination of metallic and non-metallic structures.

In FIG. 2C, the conductive layer (120) includes a combination of a plurality of nanostructures (124) and a mesh (126).

A thermally stable material has high heat capacity and/or can cause rapid heat dissipation to minimize thermal decomposition or out-gassing. More specifically, the overcoat or binder of high thermal stability that is capable of maintaining its structural integrity when heated to above 200° C., or above 300° C., or above 400° C. for a finite duration, such as for at least 10 seconds, or at least 30 second, or at least 60 seconds, or at least 2 minutes, or at least 4 minutes, or heated up to 1000° C. for on the scale of microseconds (e.g., at least 10 microseconds, or at least 100 microseconds). Structural integrity may include physical integrity (e.g., no disintegration) and/or chemical integrity (e.g., no decomposition), though a thermally stable material may be able to tolerate certain structural deformity or partial disintegration. For instance, it may melt, at least temporarily so long as it is able to absorb or dissipate heat from the conductive material. In various embodiments, the thermal stable material should be capable of conducting heat away from a conductive material when heated to above 400° C. for at least 10 seconds, or at least 30 second or at least 1 minute, or at least 4 minutes.

In various embodiments, the thermally stable material may be a spin-on dielectric material, which may be inorganic (e.g., silicon dioxide), polymeric or a mixture thereof.

Thermally stable inorganic materials that can be spun on or coated include materials comprising siloxane (—Si—O—), silazane (—NH—Si—) or silicon carbide (—Si—C—) moieties, collectively referred to herein as spin-on glass (SOG). SOG is commonly used as gap-filling and planarizing dielectric layer in the semiconductor processing.

SOG is typically deposited on a substrate by a sol-gel method and is thus compatible with the solution-based approach to forming transparent conductive films described herein. More specifically, once a stable suspension of colloidal particles (a sol) is deposited, it irreversibly transitions to a rigid or porous film. Typically, the sol-gel process produces a network of polymers having chemical moieties such as —Si—O—, —Si—NH— or —Si—C or a combination thereof through a hydrolysis-condensation reaction.

Organic polymers that have high thermal stability tend to be crystalline, have aromatic rings (including aromatic rings fused with non-aromatic rings), and one or more types of heteroatoms (e.g., nitrogen or oxygen). Exemplary polymers of high thermal stability include, without limitation, polyimides having aromatic moieties, polybenzoxazoles, etc.

Another embodiment provides a transparent conductor having an overcoat that has a high heat capacity and thermal conductivity such that the heat released by the nanostructures or mesh can be rapidly absorbed or removed in order to minimize a temperature increase in the organic phase.

More specifically, the overcoat layer may be a polymeric or resin layer heavily filled with inorganic nanoparticles. FIG. 3 shows a transparent conductive film (300) comprising a substrate (210), a conductive layer (120) disposed on the substrate (210), the conductive layer (120) having a plurality of interconnecting conductive elements (130) optionally embedded in a matrix or binder (140), and an overcoat layer (250) overlying the nanostructure conductive layer. The overcoat layer (250) comprises a plurality of high heat-capacity nanoparticles (260).

The conductive layer (120) may be in any of the configurations of FIGS. 2A, 2B and 2C.

Owing to the presence of the high heat-capacity nanoparticles, the highly-filled overcoat tends to have higher heat capacity than unfilled overcoat. Consequently, compared to unfilled overcoats, highly-filled overcoats are much less likely to have total outgassing from thermal decomposition and/or much less total mechanical deformation from heat and pressure.

High heat-capacity nanoparticles are inorganic particles, at least one dimension of which is less than 1 micron. The heat-conductive nanoparticles may be substantially spherical or elongated, for instance, in the shape of nanowires or nanotubes. Nanoparticles of metallic or metal oxide materials, such as oxides of titanium, zinc, zirconium, aluminum, and cerium, are suitable heat conductors. Certain non-metallic nanoparticles such as carbon nanotubes and silicon oxide particles may also be used.

The overcoat layer should be filled with heat-conductive nanoparticles at a loading level that confers satisfactory heat capacity. The nanoparticles may or may not be in physical contact with each other. The loading level may be ascertained empirically for specific applications. Other factors such as haze and light transmission may be altered by the amount and the type of filler nanoparticles and consideration should be given to balance any conflicting requirements. In various embodiments, the overcoat layer may be filled with at least 10% or at least 20%, or at least 30%, or at least 40% (v/v) of high heat-capacity nanoparticles. Spin-on-dielectric overcoats may comprise up to about 90% nanoparticles.

The high heat-capacity nanoparticles may be formulated in a coating solution with the polymer or resin at a predetermined loading level and coated on a mesh or nanostructure conductive layer. The overcoat may comprise polymers such as, without limitation: polyacrylics such as polymethacrylates (e.g., poly(methyl methacrylate)), polyacrylates and polyacrylonitriles, polyvinyl alcohols, polyesters (e.g., polyethylene terephthalate (PET), polyester naphthalate, and polycarbonates), polymers with a high degree of aromaticity such as phenolics or cresol-formaldehyde (Novolacs®), polystyrenes, polyvinyltoluene, polyvinylxylene, polyimides, polyamides, polyamideimides, polyetherimides, polysulfides, polysulfones, polyphenylenes, and polyphenyl ethers, polyurethane (PU), epoxy, polyolefins (e.g. polypropylene, polymethylpentene, and cyclic olefins), acrylonitrile-butadiene-styrene copolymer (ABS), cellulosics, silicones and other silicon-containing polymers (e.g. polysilsesquioxanes and polysilanes), polyvinylchloride (PVC), polyacetates, polynorbornenes, synthetic rubbers (e.g., EPR, SBR, EPDM), fluoropolymers (e.g., polyvinylidene fluoride, polytetrafluoroethylene (TFE) or polyhexafluoropropylene), copolymers of fluoro-olefin and hydrocarbon olefin (e.g., Lumiflon®), and amorphous fluorocarbon polymers or copolymers (e.g., CYTOP® by Asahi Glass Co., or Teflon® AF by Du Pont).

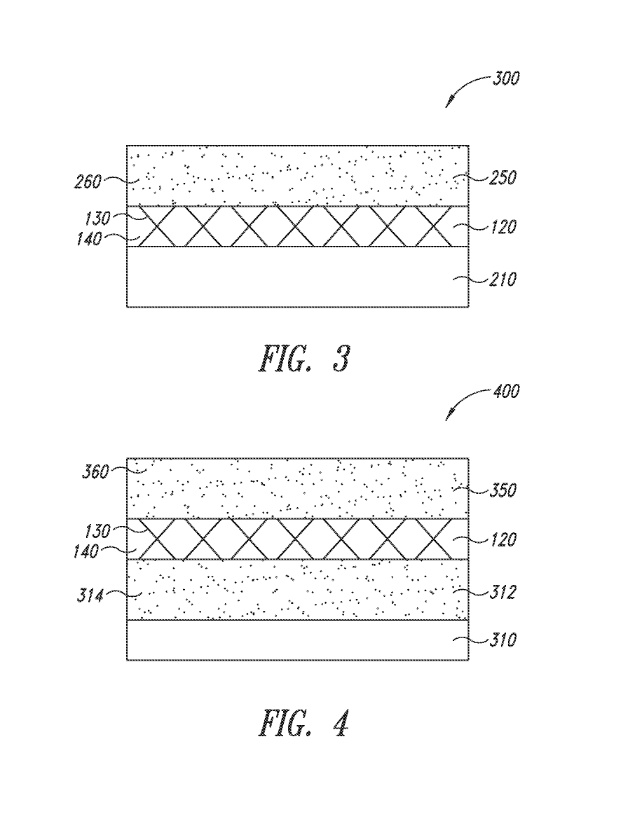

A further embodiment provides a transparent conductor having, in addition to, or in lieu of a nanoparticle-filled overcoat layer, a nanoparticle-filled hard coat layer underlying the mesh or nanostructure conductive layer. The hard coat layer can further improve thermal stability by acting as a heat sink via higher heat capacity and thermal conductivity. FIG. 4 thus shows a transparent conductive film (400) comprising a substrate (310), a hard coat layer (312) overlying the substrate (310) and comprising a second plurality of high heat-capacity nanoparticles (314), a conductive layer (120) disposed on the hard coat layer (312), the conductive layer (120) having a plurality of interconnecting conductive elements (130) optionally embedded in a matrix or binder (140), and an overcoat layer (350) overlying the conductive layer, the overcoat layer (350) further comprising a first plurality of high heat-capacity nanoparticles (360).

The various constituents of the transparent conductive film are described in further detail below.

### Conductive Nanostructures

As used herein, “conductive nanostructures” generally refer to electrically conductive nano-sized structures, at least one dimension of which (i.e., width or diameter) is less than 500 nm; more typically, less than 100 nm or 50 nm. In various embodiments, the width or diameter of the nanostructures are in the range of 10 to 40 nm, 20 to 40 nm, 5 to 20 nm, 10 to 30 nm, 40 to 60 nm, 50 to 70 nm.

One way for defining the geometry of a given nanostructure is by its “aspect ratio,” which refers to the ratio of the length and the width (or diameter) of the nanostructure. In preferred embodiments, the nanostructures are anisotropically shaped (i.e. aspect ratio≠1). The anisotropic nanostructure typically has a longitudinal axis along its length. Exemplary anisotropic nanostructures include nanowires (solid nanostructures having aspect ratio of at least 10, and more typically, at least 50), nanorod (solid nanostructures having aspect ratio of less than 10) and nanotubes (hollow nanostructures).

Lengthwise, anisotropic nanostructures (e.g., nanowires) are more than 500 nm, or more than 1 μm, or more than 10 μm in length. In various embodiments, the lengths of the nanostructures are in the range of 5 to 30 μm, or in the range of 15 to 50 μm, 25 to 75 μm, 30 to 60 μm, 40 to 80 μm, or 50 to 100 μm.

Conductive nanostructures are typically of a metallic material, including elemental metal (e.g., transition metals) or a metal compound (e.g., metal oxide). The metallic material can also be a bimetallic material or a metal alloy, which comprises two or more types of metal. Suitable metals include, but are not limited to, silver, gold, copper, nickel, gold-plated silver, platinum and palladium. It should be noted that although the present disclosure describes primarily nanowires (e.g., silver nanowires), any nanostructures within the above definition can be equally employed.

Typically, conductive nanostructures are metal nanowires that have aspect ratios in the range of 10 to 100,000. Larger aspect ratios can be favored for obtaining a transparent conductor layer since they may enable more efficient conductive networks to be formed while permitting lower overall density of wires for a high transparency. In other words, when conductive nanowires with high aspect ratios are used, the density of the nanowires that achieves a conductive network can be low enough that the conductive network is substantially transparent.

Metal nanowires can be prepared by known methods in the art. In particular, silver nanowires can be synthesized through solution-phase reduction of a silver salt (e.g., silver nitrate) in the presence of a polyol (e.g., ethylene glycol) and poly(vinyl pyrrolidone). Large-scale production of silver nanowires of uniform size can be prepared and purified according to the methods described in U.S. Published Application Nos. 2008/0210052, 2011/0024159, 2011/0045272, and 2011/0048170, all in the name of Cambrios Technologies Corporation, the assignee of the present disclosure.

### Nanostructure Conductive Layer

A nanostructure conductive layer is a conductive network of interconnecting conductive nanostructures (e.g., metal nanowires) that provide the electrically conductive media of a transparent conductor. Since electrical conductivity is achieved by electrical charge percolating from one metal nanostructure to another, sufficient metal nanowires must be present in the conductive network to reach an electrical percolation threshold and become conductive. The surface conductivity of the nanostructure conductive layer is inversely proportional to its surface resistivity, sometimes referred to as sheet resistance, which can be measured by known methods in the art. As used herein, “electrically conductive” or simply “conductive” corresponds to a surface resistivity of no more than 10⁴Ω/□, or more typically, no more than 1,000Ω/□, or more typically no more than 500Ω/□, or more typically no more than 200Ω/□. The surface resistivity depends on factors such as the aspect ratio, the degree of alignment, degree of agglomeration and the resistivity of the interconnecting conductive nanostructures.

In certain embodiments, the conductive nanostructures may form a conductive network on a substrate without a binder. In other embodiments, a binder may be present that facilitates adhesion of the nanostructures to the substrate. Suitable binders include optically clear polymers including, without limitation: polyacrylics such as polymethacrylates (e.g., poly(methyl methacrylate)), polyacrylates and polyacrylonitriles, polyvinyl alcohols, polyesters (e.g., polyethylene terephthalate (PET), polyester naphthalate, and polycarbonates), polymers with a high degree of aromaticity such as phenolics or cresol-formaldehyde (Novolacs®), polystyrenes, polyvinyltoluene, polyvinylxylene, polyimides, polyamides, polyamideimides, polyetherimides, polysulfides, polysulfones, polyphenylenes, and polyphenyl ethers, polyurethane (PU), epoxy, polyolefins (e.g. polypropylene, polymethylpentene, and cyclic olefins), acrylonitrile-butadiene-styrene copolymer (ABS), cellulosics, silicones and other silicon-containing polymers (e.g. polysilsesquioxanes and polysilanes), polyvinylchloride (PVC), polyacetates, polynorbornenes, synthetic rubbers (e.g., EPR, SBR, EPDM), and fluoropolymers (e.g., polyvinylidene fluoride, polytetrafluoroethylene (TFE) or polyhexafluoropropylene), copolymers of fluoro-olefin and hydrocarbon olefin (e.g., Lumiflon®), and amorphous fluorocarbon polymers or copolymers (e.g., CYTOP® by Asahi Glass Co., or Teflon® AF by Du Pont). Additional suitable binders include carboxy methyl cellulose (CMC), 2-hydroxy ethyl cellulose (HEC), hydroxy propyl methyl cellulose (HPMC), methyl cellulose (MC), poly vinyl alcohol (PVA), tripropylene glycol (TPG), and xanthan gum (XG).

“Substrate” refers to a non-conductive material onto which the metal nanostructure is coated or laminated. The substrate can be rigid or flexible. The substrate can be clear or opaque. Suitable rigid substrates include, for example, glass, polycarbonates, acrylics, and the like. Suitable flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067.

Typically, the optical transparence or clarity of the transparent conductor (i.e., a conductive network on a non-conductive substrate) can be quantitatively defined by parameters including light transmission and haze. “Light transmission” (or “light transmissivity”) refers to the percentage of an incident light transmitted through a medium. In various embodiments, the light transmission of the conductive layer is at least 80% and can be as high as 98%. Performance-enhancing layers, such as an adhesive layer, anti-reflective layer, or anti-glare layer, may further contribute to reducing the overall light transmission of the transparent conductor. In various embodiments, the light transmission (T %) of the transparent conductors can be at least 50%, at least 60%, at least 70%, or at least 80% and may be as high as at least 91% to 92%, or at least 95%.

Haze (H %) is a measure of light scattering. It refers to the percentage of the quantity of light separated from the incident light and scattered during transmission. Unlike light transmission, which is largely a property of the medium, haze is often a production concern and is typically caused by surface roughness and embedded particles or compositional heterogeneities in the medium. Typically, haze of a conductive film can be significantly impacted by the diameters of the nanostructures. Nanostructures of larger diameters (e.g., thicker nanowires) are typically associated with a higher haze. In various embodiments, the haze of the transparent conductor is no more than 10%, no more than 8%, or no more than 5% and may be as low as no more than 2%, no more than 1%, or no more than 0.5%, or no more than 0.25%.

### Coating Composition

The patterned transparent conductors according to the present disclosure are prepared by coating a nanostructure-containing coating composition on a non-conductive substrate. To form a coating composition, the metal nanowires are typically dispersed in a volatile liquid to facilitate the coating process. It is understood that, as used herein, any non-corrosive volatile liquid in which the metal nanowires can form a stable dispersion can be used. Preferably, the metal nanowires are dispersed in water, an alcohol, a ketone, ethers, hydrocarbons or an aromatic solvent (benzene, toluene, xylene, etc.). More preferably, the liquid is volatile, having a boiling point of no more than 200° C., no more than 150° C., or no more than 100° C.

In addition, the metal nanowire dispersion may contain additives and binders to control viscosity, corrosion, adhesion, and nanowire dispersion. Examples of suitable additives and binders include, but are not limited to, carboxy methyl cellulose (CMC), 2-hydroxy ethyl cellulose (HEC), hydroxy propyl methyl cellulose (HPMC), methyl cellulose (MC), poly vinyl alcohol (PVA), tripropylene glycol (TPG), and xanthan gum (XG), and surfactants such as ethoxylates, alkoxylates, ethylene oxide and propylene oxide and their copolymers, sulfonates, sulfates, disulfonate salts, sulfosuccinates, phosphate esters, and fluorosurfactants (e.g., Zonyl® by DuPont).

In one example, a nanowire dispersion, or “ink” includes, by weight, from 0.0025% to 0.1% surfactant (e.g., a preferred range is from 0.0025% to 0.05% for Zonyl® FSO-100), from 0.02% to 4% viscosity modifier (e.g., a preferred range is 0.02% to 0.5% for HPMC), from 94.5% to 99.0% solvent and from 0.05% to 1.4% metal nanowires. Representative examples of suitable surfactants include Zonyl® FSN, Zonyl® FSO, Zonyl® FSH, Triton (x100, x114, x45), Dynol (604, 607), n-Dodecyl b-D-maltoside and Novek. Examples of suitable viscosity modifiers include hydroxypropyl methyl cellulose (HPMC), methyl cellulose, xanthan gum, polyvinyl alcohol, carboxy methyl cellulose, and hydroxy ethyl cellulose. Examples of suitable solvents include water and isopropanol.

The nanowire concentration in the dispersion can affect or determine parameters such as thickness, conductivity (including surface conductivity), optical transparency, and mechanical properties of the nanowire network layer. The percentage of the solvent can be adjusted to provide a desired concentration of the nanowires in the dispersion. In preferred embodiments the relative ratios of the other ingredients, however, can remain the same. In particular, the ratio of the surfactant to the viscosity modifier is preferably in the range of about 80 to about 0.01; the ratio of the viscosity modifier to the metal nanowires is preferably in the range of about 5 to about 0.000625; and the ratio of the metal nanowires to the surfactant is preferably in the range of about 560 to about 5. The ratios of components of the dispersion may be modified depending on the substrate and the method of application used. The preferred viscosity range for the nanowire dispersion is between about 1 and 100 cP.

Following the coating, the volatile liquid is removed by evaporation. The evaporation can be accelerated by heating (e.g., baking). The resulting nanowire network layer may require post-treatment to render it electrically conductive. This post-treatment can be a process step involving exposure to heat, plasma, corona discharge, UV-ozone, or pressure as described below.

Examples of suitable coating compositions are described in U.S. Published Application Nos. 2007/0074316, 2009/0283304, 2009/0223703, and 2012/0104374, all in the name of Cambrios Technologies Corporation, the assignee of the present disclosure.

The coating composition is coated on a substrate by, for example, sheet coating, web-coating, printing, and lamination, to provide a transparent conductor. Additional information for fabricating transparent conductors from conductive nanostructures is disclosed in, for example, U.S. Published Patent Application No. 2008/0143906, and 2007/0074316, in the name of Cambrios Technologies Corporation.

### Conductive Grid or Mesh

The low sheet resistance grid (e.g., 126 of FIGS. 2B and 2C) provides a low resistance pathway or a network of pathways for current flow, distribution and/or collection. The low sheet resistance grid 126 includes any type of electrically conductive structure having appropriate electrical and physical properties, including metallic, non-metallic, or composite structures containing a combination of metallic and non-metallic structures. Examples of low sheet resistance grids 126 include, but are not limited to fine metal mesh (e.g., copper mesh, silver mesh, aluminum mesh, steel mesh, etc.)—deposited e.g. by sputtering or evaporation with post-patterning, preferably e.g. screen-printed metal pastes (e.g. Ag-paste), an embeddable fine metal wire or a printable solution containing one or more residual low resistance components.

The physical size and/or configuration of the low sheet resistance grid 126 is based in whole or in part upon meeting any specified electrical (e.g., sheet resistance) and physical (e.g., surface roughness and/or light transmission) requirements. The size and routing of the conductors forming the low sheet resistance grid 126 form a grid pattern used to deposit or otherwise form at least a portion of the low sheet resistance grid 126 on the substrate. In some embodiments, the width of the elements forming the low sheet resistance grid 126 can range from about 1 micron to about 300 microns. In some embodiments, the height of the elements forming the low sheet resistance grid can range from about 100 nm to about 100 microns. The open distance between the elements forming the low sheet resistance grid can range from about 100 microns to about 10 mm.

Deposition of the low sheet resistance grid 126 can be accomplished using pre-patterning, post-patterning or any combination thereof. Examples of pre-patterned, printed, low sheet resistance grids include, but are not limited to, printed silver paste grids, printed copper paste grids, micro- or nano-particle paste grids, or similar conductive paste grids. An example post-patterned low sheet resistance grid 126 is provided by the use photo-lithographic development of a previously applied conductive film to produce the low sheet resistance grid 126. Other example post-patterned low sheet resistance grids 126 include, but are not limited to, overall deposition via printing, evaporation, sputtering, electro-less or electrolytic plating, or solution processing followed by patterning via photo-lithography, screen printed resist, screen printed etchant, standard etch, laser etch, and adhesive lift off stamp.

The low sheet resistance grid may have any two-dimensional or three-dimensional geometry, shape or configuration needed to achieve a desired sheet resistance while retaining acceptable optical properties. While a greater grid density (i.e., greater low resistance pathway cross sectional area) may reduce the overall sheet resistance of the transparent conductor, a high grid density may increase the opacity of the transparent conductor to unacceptable levels. Thus, the pattern selection and physical properties of the low sheet resistance grid 126 is, at times, may represent a compromise based at least in part upon the minimizing the sheet resistance of the transparent conductor while not increasing the opacity of the transparent conductor to an unacceptable degree.

The low sheet resistance grid 126 can have any fixed, geometric or random pattern capable of providing an acceptable sheet resistance. For example, low sheet resistance grid 126 patterns can include regular or irregular width geometric arrangements such as perpendicular lines, angled lines (e.g., forming a “diamond” pattern), and parallel lines. Other patterns can use curved or arc-shaped conductors to achieve complex patterns having uniform or non-uniform sheet resistance, for example where the transparent conductor is intended for a three dimensional application. Where appropriate, for example in some OLED series interconnected cells and in forming photovoltaic modules, the low sheet resistance grid 126 can be formed using two or more patterns, for example a grid formed using parallel lines bounded by a larger pattern, such as a hexagon or rectangle. In another embodiment, the low sheet resistance grid 126 may be a comb-like structure linking series interconnected thin film photovoltaic stripes.

### EXAMPLES

### Example 1

### Standard Preparation of Coating Compositions of Conductive Nanostructures

A typical coating composition for depositing metal nanowires comprises, by weight, from 0.0025% to 0.1% surfactant (e.g., a preferred range is from 0.0025% to 0.05% for a fluorosurfactant), from 0.02% to 4% viscosity modifier (e.g., a preferred range is 0.02% to 0.5% for hydroxypropyl methylcellulose (HPMC), from 94.5% to 99.0% solvent and from 0.05% to 1.4% metal nanowires.

The coating composition can be prepared based on a desired concentration of the nanowires, which is an index of the loading density of the final conductive film formed on the substrate.

The coating composition can be deposited on a substrate according to, for example, the methods described in U.S. Pat. No. 8,049,333, and U.S. Published Application No. 2011/0174190.

As understood by one skilled in the art, other deposition techniques can be employed, e.g., sedimentation flow metered by a narrow channel, die flow, flow on an incline, slit coating, gravure coating, microgravure coating, bead coating, dip coating, slot die coating, and the like. Printing techniques can also be used to directly print an ink composition onto a substrate with or without a pattern. For example, inkjet, flexoprinting and screen printing can be employed. It is further understood that the viscosity and shear behavior of the fluid as well as the interactions between the nanowires may affect the distribution and interconnectivity of the nanowires deposited.

A sample conductive nanostructure dispersion was prepared that comprised silver nanowires as fabricated in Example 1, a surfactant (e.g., Triton), and a viscosity modifier (e.g., low molecular-weight HPMC) and water. The final dispersion included about 0.4% silver and 0.4% HPMC (by weight), i.e., the weight ratio is 1:1.

### Example 2

### Silver Nanowire Layers Coated with Spin-on-Glass (SOG)

1. Preparation of Silver Nanowire Films with and without Ar Plasma Treatment

A coating solution of silver nanowires (AgNW) was prepared according to the general method described in Example 1. The HPMC were obtained from Dow Chemicals (Methocel® 311 and K100).

The coating solution was spun onto eight glass samples (slides). The AgNW-coated glass samples were then dried at 50° C. for 90 seconds and baked at 140° C. for 90 seconds. The AgNW film samples were split into two sets of four samples. The first set had their initial sheet resistances measured. The second set of four films was subjected to argon (Ar) plasma treatment to remove the binder (e.g., HPMC). See Table 1. The sheet resistances were measured following the Ar plasma treatment.

TABLE 1

| Sample No. | HPMC-Methocel ® | Ar Plasma |
|---|---|---|
| 1 | 311 | no |
| 2 | 311 | no |
| 3 | 311 | yes |
| 4 | 311 | yes |
| 5 | K100 | no |
| 6 | K100 | no |
| 7 | K100 | yes |
| 8 | K100 | yes |

2. Coating Spin-on Glass on the AgNW Films

The Spin-on glass (SOG) was obtained from Silec Co, product number SG230.

Both sets of samples (1-8) were coated with SOG using the following process: (1) dilute the SG230 with isopropyl alcohol (IPA) (1:1 by volume or 1:3 by volume), (2) spin the resulting SOG solution onto the AgNW film at 1000 rpm for 30 seconds and (3) bake the samples for 5 minutes at 140° C.

Table 2 shows the initial sheet resistance (SR)/light transmission (T) and haze (H) of the AgNW films and the contact resistances of the SOG-coated AgNW films.

TABLE 2

| | Initial | | | after SOG deposition | | |
|---|---|---|---|---|---|---|
| | SR | T | H | SR | T | H |
| | (t = 0) | (t = 0) | (t = 0) | (t = 0) | (t = 0) | (t = 0) |
| 1 | 45.8 | 90.9 | 1.09 | 45.7 | 90.7 | 0.88 |
| 2 | 48.0 | 90.9 | 1.10 | 49.8 | 90.7 | 0.91 |
| 3 | 40.1 | 90.8 | 1.05 | 42.5 | 92.2 | 0.843 |
| 4 | 39.0 | 90.7 | 0.96 | 41.6 | 92.1 | 0.77 |
| 5 | 54.7 | 91.8 | 0.88 | 60.4 | 92.6 | 0.58 |
| 6 | 53.8 | 91.7 | 0.80 | 60.0 | 92.7 | 0.53 |
| 7 | 62.0 | 91.7 | 0.70 | 67.6 | 93.2 | 0.47 |
| 8 | 59.4 | 91.7 | 0.66 | 64.5 | 93.2 | 0.48 |

Samples with higher dilution showed better contact resistance, indicating a thinner SOG film. A slight increase in sheet resistance after the SOG deposition was observed, but the overall integrity of the AgNW was still preserved. Moreover, the transmission increased slightly and the haze decreased slightly due to the presence of the SOG in the optical stack.

### Example 3

### Thermal Stability of SOG-Coated Films

The samples of Example 2 were exposed to heat treatment to investigate the thermal stability of the AgNW films. A set of four samples were heated at 350° C. for one minute (t=1) and another set of four samples were heated to 400° C. for one minute (t=1) in a furnace. The sheet resistance (SR), light transmission (T) and haze (H) after the heat treatment are shown in Table 3.

TABLE 3

| | after SOG deposition | | | Heating at 350° C. for 1 min | | | Heating at 400° C. for 1 min | | |
|---|---|---|---|---|---|---|---|---|---|
| | SR (t = 0) | T (t = 0) | H (t = 0) | SR (t = 1) | T (t = 1) | H (t = 1) | SR (t = 1) | T (t = 1) | H (t = 1) |
| 1 | 45.7 | 90.7 | 0.88 | 47.6 | 91 | 0.95 | | | |
| 2 | 49.8 | 90.7 | 0.91 | | | | 51.3 | 91.2 | 0.99 |
| 3 | 42.5 | 92.2 | 0.843 | 43.0 | 92.6 | 0.88 | | | |
| 4 | 41.6 | 92.1 | 0.77 | | | | 48.3 | 91.2 | 0.99 |
| 5 | 60.4 | 92.6 | 0.58 | 75.6 | 92.9 | 0.56 | | | |
| 6 | 60.0 | 92.7 | 0.53 | | | | 75.1 | 93.0 | 0.54 |
| 7 | 67.6 | 93.2 | 0.47 | 81.0 | 93.5 | 0.47 | | | |
| 8 | 64.5 | 93.2 | 0.48 | | | | 90.9 | 93.8 | 0.62 |

As shown, the sheet resistance of samples made from ink with Methocel® K100 rose more sharply than those made with Methocel® 311. Nevertheless, without the SOG overcoat, the nanowires disintegrate at around 180° C. Thus, the ability of the SOG-coated nanowire film to withstand 400° C. for a substantial amount of time indicates that SOG provides thermal protection and prevents the nanowires from disintegrating.

Sustainable thermal stability was observed in samples with Methocel® 311 (Samples #1 and 3) when they were further heated at 400° C. for 4 minutes (t=4) and well beyond 4 minutes. See Table 4.

A decrease in haze were observed in samples with Methocel®K100 (Samples #6 and 8), which suggested at least partial disintegration of the nanowires. Subsequent optical microscopic data confirm the structural disintegration and disappearance of the silver nanowires in these samples.

TABLE 4

| | after SOG deposition | | | Heating at 400° C. for 1 min | | | Heating at 400° C. for 4 min | | |
|---|---|---|---|---|---|---|---|---|---|
| | SR (t = 0) | T (t = 0) | H (t = 0) | SR (t = 1) | T (t = 1) | H (t = 1) | SR (t = 4) | T (t = 4) | H (t = 4) |
| 1 | 45.7 | 90.7 | 0.88 | | | | | | |
| 2 | 49.8 | 90.7 | 0.91 | 51.3 | 91.2 | 0.99 | 50.45 | 91.2 | 1.04 |
| 3 | 42.5 | 92.2 | 0.843 | | | | | | |
| 4 | 41.6 | 92.1 | 0.77 | 48.3 | 91.2 | 0.99 | 47.5 | 92.9 | 0.90 |
| 5 | 60.4 | 92.6 | 0.58 | | | | | | |
| 6 | 60.0 | 92.7 | 0.53 | 75.1 | 93.0 | 0.54 | 82.8 | 92.9 | 0.56 |
| 7 | 67.6 | 93.2 | 0.47 | | | | | | |
| 8 | 64.5 | 93.2 | 0.48 | 90.9 | 93.8 | 0.62 | 100.2 | 93.7 | 0.50 |

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transparent conductive film, comprising:
a substrate;
a conductive layer disposed on the substrate, the conductive layer having a plurality of interconnecting conductive elements optionally embedded in a binder; and
an overcoat layer overlying the conductive layer, wherein at least one of the binder and the overcoat is a thermally stable material.

2. The transparent conductive film of claim 1 wherein the binder is polyimide or polybenzoxazoles.

3. The transparent conductive film of claim 1 wherein the overcoat is polyimide or polybenzoxazoles.

4. The transparent conductive film of claim 1 wherein the overcoat is a spin-on dielectric layer.

5. The transparent conductive film of claim 4 wherein the spin-on dielectric layer comprises a network of polymers having moieties of —Si—O—, —Si—NH—, —Si—C—, or a combination thereof.

6. The transparent conductive film of claim 4 wherein the overcoat is a spin-on glass.

7. The transparent conductive film of claim 1 wherein the thermally stable material is capable of maintaining its structural integrity when heated to above 400° C. for at least 1 minute.

8. The transparent conductive film of claim 1 wherein the thermally stable material is capable of maintaining its structural integrity when heated up to 1000° C. for at least 100 microseconds.

9. The transparent conductive film of claim 1 wherein the overcoat layer comprises a first plurality of high heat-capacity nanoparticles.

10. The transparent conductive film of claim 9, further comprising a hard coating layer interposed between the substrate and the conductive layer, the hard coat layer having a second plurality of high heat-capacity nanoparticles.

11. The transparent conductive film of claim 9 wherein the high heat-capacity nanoparticles are oxides of silicon, titanium, zinc, zirconium, aluminum, and cerium.

12. The transparent conductive film of claim 9 wherein the high heat-capacity nanoparticles are carbon nanotubes.

13. The transparent conductive film of claim 1 wherein the conductive elements are a plurality of conductive nanostructures.

14. The transparent conductive film of claim 13 wherein the conductive nanostructures are silver nanowires.

15. The transparent conductive film of claim 1 wherein the conductive elements form a conductive mesh.

16. The transparent conductive film of claim 15 wherein the conductive mesh is formed of metallic paste or conductive wires.

17. The transparent conductive film of claim 1 wherein the conductive layer comprises a plurality of conductive nanostructures electrically coupled to a conductive mesh.
